(19) United States
(12) Patent Application Publication
(10) Pub. No.: US 2002/0137325 A1
(43) Pub. Date: Sep. 26, 2002

(54) Method for forming bumps

(76) Inventor: Tung-Liang Shao, Taoyuan (TW)

Correspondence Address: J C Patents Inc, 4 Venture, Suite 250, Irvine, CA, 92618, US

(21) Appl. No.: 09/853,987

(22) Filed: May 11, 2001

(30) Foreign Application Priority Data
Mar. 22, 2001 (TW) 90106702

(51) Int. Cl. H01L 21/44

(52) U.S. Cl. 438/613; 438/615

(57) ABSTRACT

A method of forming a bump on a wafer is provided. A thick photoresist having a plurality of openings is formed on the wafer to expose the bonding pads. A solder paste is filled in the openings of the thick photoresist. A stencil that has a plurality of openings corresponding to those of the photoresist is applied over the wafer. After the stencil is removed, a reflow process is carried out to form bumps. The thick photoresist is then removed. The bumps are formed in two steps using a thick photoresist and a stencil, resulting in an increased height and uniformity after reflow.

### CROSS-REFERENCE TO RELATED APPLICATION

This application claims the priority benefit of Taiwan application serial no. 90106702, filed Mar. 22, 2001.

### BACKGROUND OF THE INVENTION

### Field of the Invention

The invention relates to a method of forming a bump. More particularly, the invention relates to a method of forming a bump that is formed in two steps using a thick photoresist and a stencil, resulting in an increased height and uniformity after reflow.

### Description of the Related Art

As the electronic technology progresses, emphasis is more particularly placed on the miniaturization of electronic products. This miniaturization results in electronic products that are more complicated and denser. In the electronics industry, package structures that have small dimensions and high density are required for packaging of electronic devices. Many types of packages have been developed such as ball grid array (BGA) packages, chip-scale packages (CSP), flip-chip (F/C) packages, and multi-chip module (MCM) packages.

IC package density refers to pin counts per unit area of the package. In a high-density IC package, a shortened connection path helps increase signal transmission speed. Therefore, bumps are increasingly used as connections in a high-density package.

In a conventional method of forming a bump, an under ball metallurgy (UBM) is formed on a bonding pad on the wafer. A resist having a plurality of openings is applied on the wafer, the opening exposing the bonding pad underneath. Then, a solder paste is filled in the openings. A reflow process is carried out to form a bump on the bonding pad. Finally, the photoresist is removed. Since the solder paste is filled in the photoresist, the bump formed of the solder paste is limited by the thickness of the photoresist.

### SUMMARY OF THE INVENTION

It is one object of the present invention is to provide a method of forming a bump. In the present invention, a thick photoresist having openings is used to define the position where the solder paste is filled. A stencil also having openings which correspond to those of the thick photoresist is additionally used. After the solder paste is fill through the thick photoresist and the stencil, a reflow process is carried out to increase the height and uniformity of the bump thus formed.

To achieve the foregoing and other objects, the present invention provides a method of forming a bump. A wafer that has a plurality of chips, each of which is provided with a plurality of bonding pads and a passivation layer that protects the chip and exposes the bonding pads, is provided. Each of the bonding pads is further provided with an under ball metallurgy (UBM) thereon. A photoresist with a plurality of first openings corresponding to the UBMs is formed over the wafer. A solder paste is filled in the first openings. A stencil having a plurality of second openings is applied over the photoresist, such that the second openings correspond to the first openings. The solder paste is filled in the second openings. After the stencil is removed, a reflow process is carried out. The photoresist is removed.

In the present invention, the bump is formed in two steps using a thick photoresist and a stencil. After reflow, the bump has a desirable height without the limitation of a conventional bump, resulting in an increased height and uniformity.

It should be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 through FIG. 3 are cross-sectional views schematically illustrating various stages in a wafer bumping process according to a first preferred embodiment of the present invention.

### DESCRIPTION OF THE PREFERRED EMBODIMENTS

The following detailed description of the embodiments and examples of the present invention with reference to the accompanying drawings is only illustrative and not limiting.

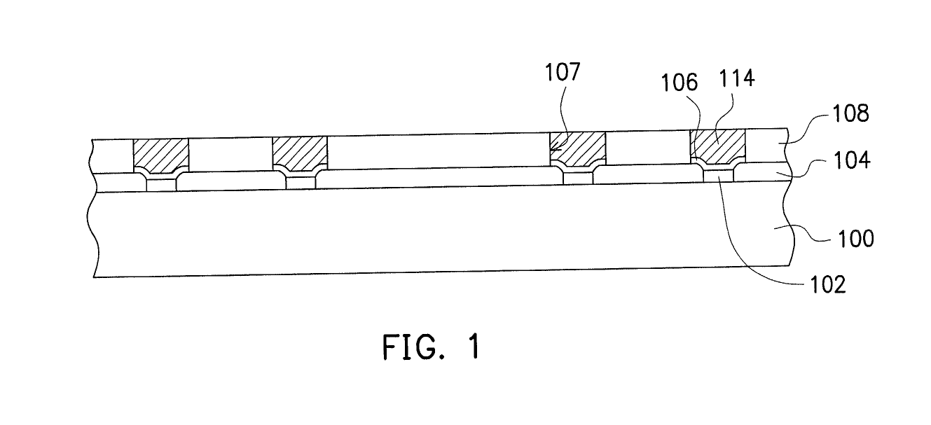

FIG. 1 through FIG. 3 are schematic, cross-sectional views showing bump formation according to a preferred embodiment of the present invention.

With reference to FIG. 1, a wafer 100 has a plurality of chips each of which is provided with a plurality of bonding pads 102 and a passivation layer 104 thereon. Further, under ball metallurgies (UBM) 106 are formed on the bonding pads 102, respectively. The UBMs 106 can be made of multi-layers of chromium/chromium-copper/copper, for example. A patterned photoresist 108 having a plurality of openings corresponding to the UBMs 106 to expose the UBMs 106 underneath is formed over the wafer 100. Then, a solder paste 114 is filled in the first openings 107, for example by printing. The patterned photoresist 108 can be, for example, a liquid photoresist or a dry film.

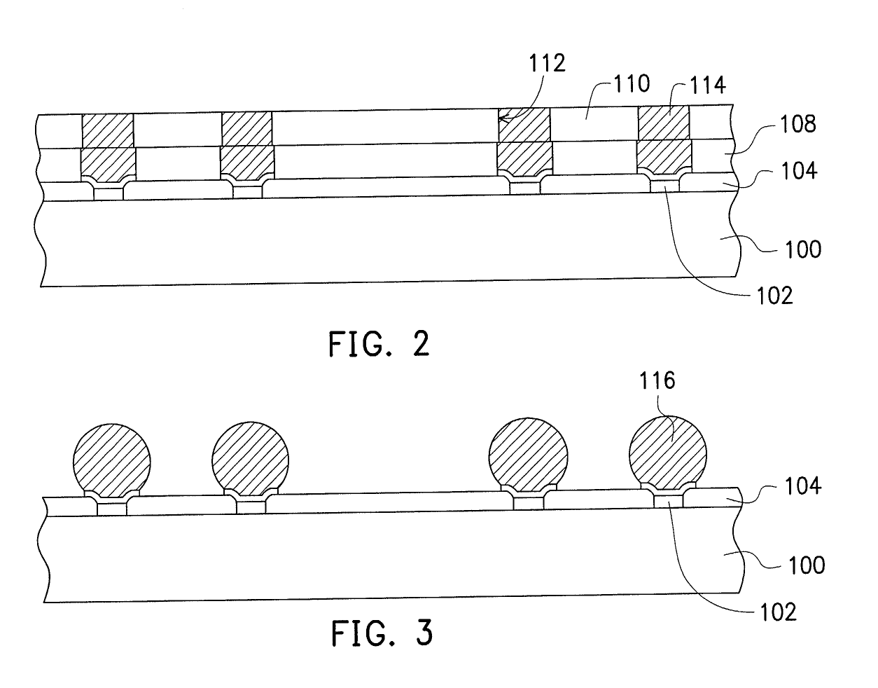

Since the patterned photoresist 108 has a limited thickness, the solder paste 114 filled in the first opening 107 in the photoresist 108 can not form a bump having a desirable height. In order to overcome this disadvantage, the inventor puts a stencil 110 on the patterned photoresist 108, as shown in FIG. 2, to form a bump having the desirable height.

Referring to FIG. 2, a stencil 110 having a plurality of second openings 112 corresponding to the first openings 107 is applied on the patterned photoresist 108. A solder paste 114 is then filled in the first openings 107 and the second openings 112, for example by printing. The solder paste 114 is, for example, a tin-lead paste that can have various ratios SnₓPb_{y}. However the solder paste 114 also can be composed of other solder constituents not recited in the specification of the present invention. Referring to FIG. 3, the stencil 110 is then removed. The solder paste 114 is then reflowed to form a plurality of bumps 116. Then, the patterned photoresist 108 is removed.

If the same content of solder paste is added to a short bump and a high bump having the same diameter, the short bump grows up more significantly than the high bump. In other words, regardless of the amount of solder paste added to the bump, the larger the volume of the bump is, the less the height of the bump increases.

Therefore, the solder paste 114 filled in the first opening 107 and the second opening 112 forms a significantly higher bump 116 by using the patterned photoresist 105 and the stencil 110 and makes the bump more uniform.

From a view of foregoing, the method of forming a bump according to the present invention can provide the following advantages:

1. By using a thick photoresist and a stencil, the bump after reflow has a desirable height, without the limitation of a conventional bump.

2. In the present invention, the bump is formed in two steps, resulting in an increased height and uniformity after reflow.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

What is claimed is:

1. A method of forming a bump, comprising:
providing a wafer that has a plurality of chips on each of which is provided a plurality of bonding pads and each of which has a passivation layer that protects the chip and exposes the bonding pads, wherein each of the bonding pads is further provided with an under ball metallurgy (UBM) thereon;
forming a photoresist over the wafer, wherein the photoresist has a plurality of first openings corresponding to the UBMs, respectively;
filling a solder paste in the first openings;
applying a stencil that has a plurality of second openings over the photoresist, such that the second openings correspond to the first openings;
filling the solder paste in the second openings;
removing the stencil; and
performing a reflow process, and removing the photoresist.

2. The method of claim 1, wherein the patterned photoresist is a liquid photoresist or a dry film.

3. The method of claim 1, wherein the solder paste is a tin lead paste with various ratios.

4. A method of forming a bump, comprising:
providing a wafer that has a plurality of chips, each of which is provided with a plurality of bonding pads and has a passivation layer that protects the chip and exposes the bonding pads, wherein each of the bonding pads is further provided with a under ball metallurgy (UBM) thereon;
forming a photoresist over the wafer, wherein the photoresist has a plurality of first openings corresponding to the UBMs respectively;
filling a solder paste in the first openings;
applying a stencil that has a plurality of second openings over the photoresist, such that the second openings correspond to the first openings;
filling the solder paste in the first openings and the second openings;
removing the stencil; and performing a reflow process, and removing the photoresist.

5. The method of claim 4, wherein the photoresist is a liquid photoresist or a dry film.

6. The method of claim 4, wherein the solder paste is a tin lead paste with various ratios.
